(19) United States
(12) Patent Application Publication
(10) Pub. No.: US 2026/0238374 A1
(43) Pub. Date: Aug. 13, 2026

(54) GENERATING A PLURALITY OF PULSE TRAINS FROM A MICRO COMB LASER

(71) Applicant: NEWPHOTONICS LTD., Kfar-Mordehai (IL)

(72) Inventors: Yosef BEN-EZRA, Petah Tikva (IL); Yaniv BEN-HAIM, Kfar-Mordehai (IL)

(73) Assignee: NEWPHOTONICS LTD., Kfar-Mordehai (IL)

(21) Appl. No.: 19/153,666

(22) PCT Filed: Jan. 4, 2024
(86) PCT No.: PCT/IL2024/050014

§ 371 Date: Aug. 5, 2025

Related U.S. Application Data
(60) Provisional application No. 63/484,226, filed on Feb. 10, 2023.

(51) Int. Cl. H04J 14/02; H01S 3/00; H01S 3/10

(52) U.S. Cl. CPC H04J 14/0307; H01S 3/0057; H01S 3/0078; H01S 3/10015

(57) ABSTRACT

A method and system, the method comprising: obtaining a plurality of coherent subcarriers, each of the plurality of coherent subcarriers having a subcarrier frequency out of a collection of subcarrier frequencies, wherein the collection of subcarrier frequencies are equally spaced; filtering a first group of subcarriers having consecutive frequencies of the collection of subcarrier frequencies, thereby obtaining a first sequence of equidistant pulses in time domain; and filtering a second group of subcarriers having consecutive frequencies of the collection of carrier frequencies, thereby obtaining a second sequence of equidistant pulses in the time domain, wherein the second group is different from the first group, thereby obtaining at least two sequences of equidistant time domain pulses, the at least two sequences of equidistant time domain pulses having different wavelengths.

### CROSS-REFERENCE TO RELATED APPLICATION

This application claims the benefit of U.S. Provisional Patent Application No. 63/484,226, filed Feb. 10, 2023, entitled “Generating a Plurality of Pulse Trains from a Micro Comb Laser” which is hereby incorporated by reference in its entirety without giving rise to disavowment.

### TECHNICAL FIELD

The present disclosure relates to using a comb laser source in general, and to using a comb laser source for generating and using a plurality of equidistant time domain pulse trains, in particular.

### BACKGROUND

A frequency comb is a laser source whose spectrum consists of a series of discrete, equally spaced frequency lines.

The frequency domain representation of a perfect frequency comb is a series of delta functions spaced according to fₙ=f₀+nfᵣ, wherein n is an integer, fᵣ is the comb tooth spacing which is equal to the mode-locked laser's repetition rate or, alternatively, the modulation frequency, and f₀ is the carrier offset frequency, which is lower than fᵣ.

Comb lasers can be implemented in a variety of ways, two of which include semiconductor mode lock laser, made of a semiconductor having a saturable absorber area, and a micro-ring comb laser using a non-linear effect of a micro ring. These comb lasers are collectively referred to hereinafter as micro comb lasers.

Referring now to FIG. 1, showing a schematic illustration of the output of a micro comb laser, comprising a sequence of equidistant coherent light subcarriers, as used in some exemplary embodiments of the disclosure.

The output comprises a plurality of subcarriers, such as subcarriers 104, 108, 112 and 116, each having a subcarrier frequency, wherein the subcarrier frequencies are equally distanced, i.e., the frequency distance between any two consecutive subcarriers is constant. In the example of FIG. 1, the frequencies are equally spaced over the range of about 1530 and about 1630. FIG. 1 also shows noise 120 at a significantly lower amplitude than the amplitude of the prominent subcarriers.

While FIG. 1 shows the wavelength range of about 1530 nm to about 1630 nm, this is merely an example and other wavelength ranges may be produced by appropriate design of the micro rings and the distributed feedback (DFB) laser source. For example an O-band DFB laser source may generate a wavelength range of 1270 nm to 1330 nm.

Referring now to FIG. 2, showing a schematic illustration of an exemplary micro ring comb laser system, as used in some exemplary embodiments of the disclosure.

The system comprises a DFB laser source 200, emitting light 204 at a predetermined frequency. The light is coupled to the integrated photonic circuit through an optical coupler and then carried over a waveguide 216, which is preferably an ultra low loss waveguide.

The light is coupled to a Micro-Ring Resonator (MRR), generally referenced 206. MRR 206 which comprises a micro resonator ring 208 and a thermal heater ring 212 for heating and thereby fine tuning the resonance frequency of micro resonator ring 208, thus adjusting the resonance frequency to the frequency of light source (200). It is appreciated that ring 208 resonates wavelengths for which its perimeter divided by the wavelength is an integer number, i.e., (2*π*r)/λ=N wherein r is the ring radius and Ais the wavelength of light 204. Thus, in order for the ring to resonate a certain wavelength, its perimeter needs to be adjusted to correspond to the wavelength, wherein the adjustment may be performed by thermal heater ring 212.

Thus, output light 216 comprises subcarriers at equidistant frequencies, as shown in FIG. 1.

Comb lasers are used in the communication world for a variety of purposes as a source generating a plurality of wavelengths. In some exemplary uses, the wavelengths may be separated, and one or more of them may be modulated, such that a lot of data can be transmitted at high rate.

### BRIEF SUMMARY

One exemplary embodiment of the disclosed subject matter is a method comprising: obtaining a plurality of coherent subcarriers, each of the plurality of coherent subcarriers having a subcarrier frequency out of a collection of subcarrier frequencies, wherein the collection of subcarrier frequencies are equally spaced; filtering a first group of subcarriers having consecutive frequencies of the collection of subcarrier frequencies, thereby obtaining a first sequence of equidistant pulses in time domain; and filtering a second group of subcarriers having consecutive frequencies of the collection of carrier frequencies, thereby obtaining a second sequence of equidistant pulses in the time domain, wherein the second group is different from the first group, thereby obtaining at least two sequences of equidistant time domain pulses, the at least two sequences of equidistant time domain pulses having different wavelengths. Within the method, a first wavelength of the first sequence of equidistant pulses in the time domain optionally depends on a central frequency of the first group of subcarriers, and a second wavelength of the second sequence of equidistant time domain pulses depends on a central frequency of the second group of subcarriers. Within the method, the first group of subcarriers and the second group of subcarriers optionally do not have any common subcarrier. Within the method, a smaller number of subcarriers in the first group of subcarriers optionally provides for wider pulses in the first sequence of equidistant time domain pulses, a larger number of subcarriers in the first group of consecutive light waves optionally provides narrower pulses in the first sequence of equidistant time domain pulses, a smaller number of subcarriers in the second group of consecutive light waves optionally provides wider pulses in the second sequence of equidistant time domain pulses, and a larger number of subcarriers in the second group of consecutive light waves optionally provides narrower pulses in the second sequence of equidistant time domain pulses. The method can further comprise providing the first sequence of equidistant time domain pulses to a first Chirped Bragg Grating filter to obtain a first sequence of reshaped equidistant time domain pulses, or providing the second sequence of equidistant time domain pulses to a second Chirped Bragg Grating filter to obtain a second sequence of reshaped equidistant time domain pulses. The method can further comprise transmitting the first sequence of reshaped equidistant time domain pulses or the second sequence of reshaped equidistant time domain pulses as modulated to a semiconductor optical amplifier (SOA) for amplification. The method can further comprise modulating the first sequence of reshaped equidistant time domain pulses or the second sequence of reshaped equidistant time domain pulses. The method can further comprise transmitting the first sequence of equidistant time domain pulses or the second sequence of equidistant time domain pulses as modulated to a SOA for amplification. The method can further comprise using the first sequence of equidistant time domain pulses or the second sequence of equidistant time domain pulses as an optical clock. The method can further comprise providing the first sequence of equidistant time domain pulses to a first Variable Optical Attenuator (VOA) to obtain a first high rate sequence of single photons at a wavelength of the first sequence of equidistant time domain pulses, or providing the second sequence of equidistant time domain pulses to a second VOA to obtain a second high rate sequence of single photons at a wavelength of the second sequence of equidistant time domain pulses. The method can further comprise using the first high rate sequence of single photons or the second high rate sequence of single photons as quantum bits source. Within the method each of the first group of consecutive light waves and the second group of consecutive light waves, optionally comprises at least 8 light waves.

Another exemplary embodiment of the disclosed subject matter is a system comprising: a laser source for emitting a light wave; a mechanism for generating a plurality of coherent subcarriers from the light wave, each of the plurality of coherent subcarriers having a subcarrier frequency out of a collection of carrier frequencies, wherein the collection of subcarrier frequencies are equally spaced; at least a first filter for filtering a first group of subcarriers having consecutive frequencies of the collection of subcarrier frequencies, thereby obtaining a first sequence of equidistant pulses in time domain; at least a second filter for filtering a second group of subcarriers having consecutive frequencies of the collection of subcarrier frequencies, thereby obtaining a second sequence of equidistant pulses in time domain; at least one item selected from the group consisting of: an electrical to optical convertor for converting electrical data into optical data and modulating the first sequence of equidistant pulses or the second sequence of equidistant pulses and a semiconductor optic amplifier for amplifying the light wave to obtain at least one optical data signal; a variable optic attenuator for transforming the first sequence of equidistant pulses or the second sequence of equidistant pulses into a single photon sequence; and a semiconductor optic amplifier for amplifying the light wave, thereby creating an optical clock signal, and an array waveguide grating for multiplexing the at least one optical data signal, the single photon sequence or the optical clock signal into a unified light beam. The system can further comprise a receiver system comprising: an array waveguide grating for demultiplexing the unified light beam; and at least one item selected from the group consisting of: a photodetector for receiving a pulse train demultiplexed from the unified light beam, and a trans impedance amplifier for obtaining electronic data or a clock pulse; and a single photon avalanche photodetector for obtaining a single photon sequence.

### THE BRIEF DESCRIPTION OF THE SEVERAL VIEWS OF THE DRAWINGS

The present disclosed subject matter will be understood and appreciated more fully from the following detailed description taken in conjunction with the drawings in which corresponding or like numerals or characters indicate corresponding or like components. Unless indicated otherwise, the drawings provide exemplary embodiments or aspects of the disclosure and do not limit the scope of the disclosure. In the drawings:

FIG. 1 is a schematic illustration of the output of a micro comb laser, comprising a sequence of equidistant light subcarriers, as used in some embodiments of the disclosure;

FIG. 2 is a schematic illustration of an exemplary micro ring comb laser system, as used in some exemplary embodiments of the disclosure;

FIGS. 3A and 3B show selected groups of consecutive subcarriers, in accordance with some exemplary embodiments of the disclosure;

FIGS. 4A and 4B show pulse trains resulting from the subcarriers groups of FIGS. 3A and 3B, in accordance with some exemplary embodiments of the disclosure;

FIGS. 5A-5E shows pulse trains obtained from groups of subcarriers having different numbers of harmonics;

FIG. 6 is a schematic illustration of a sliced micro ring comb laser, in accordance with some exemplary embodiments of the disclosure;

FIG. 7 is a schematic block diagram in a system for using a plurality of equidistant pulse trains, in accordance with some exemplary embodiments of the disclosure;

FIG. 8 is a schematic block diagram of a receiver system, in accordance with some exemplary embodiments of the disclosure; and

FIG. 9 is a flowchart of a method for generating and using pulse trains from a micro comb laser, in accordance with some exemplary embodiments of the disclosure.

### DETAILED DESCRIPTION

One technical problem handled by the disclosure is the need to generate a plurality of accurate high repetition rate equidistant pulse trains having different central frequencies.

Another technical problem handled by the disclosure is the need to enable a variety of uses for the equidistant pulse trains, such as data transmission, co-packaged optics, machine learning, spectroscopy, and others, at high reliability, wherein in some embodiments, it may be important that the pulse trains have the exact same repetition rate.

One technical solution of the disclosure relates to obtaining a plurality of coherent light waves, also referred to as subcarriers, having equally spaced frequencies, such as the frequencies emitted by a single micro comb laser. The light waves may be provided to an optical splitter for splitting the power of the light beam into a plurality of light beams, such that each may be processed separately simultaneously.

A first group of the subcarriers, for a non-limiting example between about 8 to about 32 consecutive subcarriers output by the optical splitter may be filtered from the plurality of subcarriers, for example by a first optical filter.

The ensemble of the subcarriers in the first group forms an equidistant pulse train in the time domain, wherein the pulses in the pulse train are of a wavelength range having the central wavelength corresponding to the central frequency of the first optical filter.

A second group of the subcarriers, for a non-limiting example also between about 8 to about 32 consecutive subcarriers output by the optical splitter may be filtered from the plurality of subcarriers, for example by a second optical filter. The first and second groups of subcarriers may have no common subcarrier.

The ensemble of the subcarriers in the second group forms a second equidistant pulse train in the time domain, wherein the pulses in the second pulse train are of a wavelength range having a central wavelength corresponding to the central frequency of the second optical filter.

Thus, the central wavelengths of the first and second pulse trains are different. However, the pulse rate in the two pulse trains is equal and is determined by the distance between consecutive frequencies in the obtained plurality of subcarriers, and is thus equal for the first and second pulse trains.

Further groups of the subcarriers may also be separated from the received collection of subcarriers which provide pulse trains in the time domain, each of a different wavelength, since the central wavelength of each of the pulse trains is equal to the central wavelength of the subcarriers of the group of that generates the pulse train. It is appreciated that all pulse trains are equidistant, and all share the same time difference between consecutive pulses.

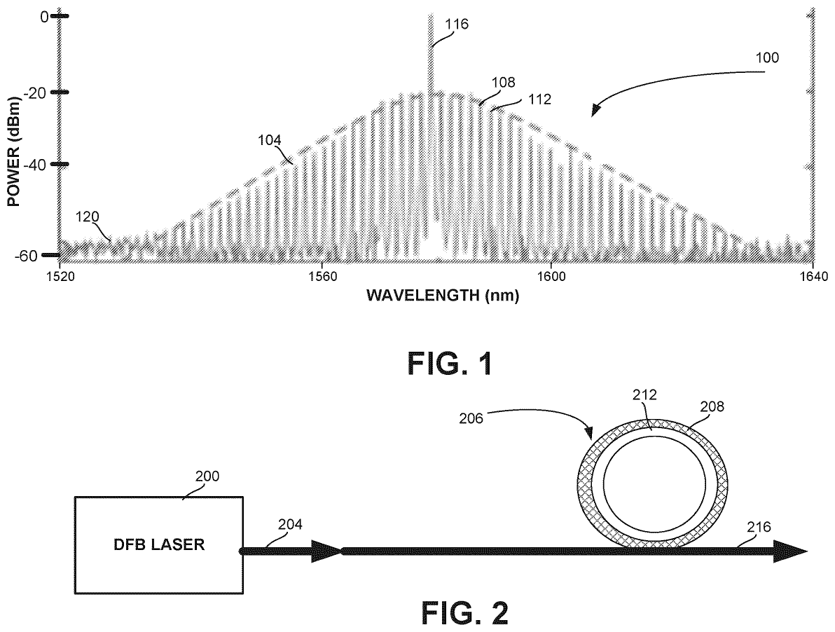

It is also appreciated that the width of the pulses in each pulse train depends on the number of consecutive subcarriers that form the pulse train in the time domain. Thus, a larger number of subcarriers in the group accounts for a narrower width of each pulse of the pulse train, since short pulses are changed faster than longer ones, therefore the short pulses consist of higher frequencies, meaning higher bandwidth will have more frequencies, and vice versa. Thus, the number of groups and the number of subcarriers in each group need to be selected such that pulses of different pulse trains do or do not overlap, as required. As seen in FIG. 1, the emitted spectrum of the micro ring comb laser is not uniform but rather bell shaped. By selecting an appropriate range from the spectrum the shape and width of the individual pulses in each pulse train can be improved in accordance with the requirements, while keeping the same repetition rate. It is appreciated that by selecting a limited number of consecutive frequencies the amplitude of the selected frequencies is within a relatively small range.

One or more of the pulse trains may be reshaped to obtain a desired pulse shape, for example using a Chirped Bragg Grating filter.

Another technical solution of the disclosure relates to using one or more of the pulse trains as an optical clock, due to its accurate high repetition rate.

Yet another technical solution of the disclosure relates to using one or more of the pulse trains for carrying data, by modulating each pulse trains in accordance with digital or analog data, thereby generating one or more high repetition rate modulated signals.

Yet another technical solution of the disclosure relates to attenuating the pulses of the pulse trains, to reduce the number of photons in each pulse to a single photon of the same color as the relevant pulse, thereby generating a high rate sequence of single photons at a wavelength of the pulse train, which may be a source for quantum bit photons.

Yet another technical solution of the disclosure relates to the time domain multiplexing of different pulse trains having different central wavelengths, creating a higher data rate and achieving both time and frequency separation of different channels.

Yet another technical solution of the disclosure relates to multiplexing one or more modulated pulse trains carrying different types of data or data from different sources, and/or an optical clock, and/or one or more single photon sequences, all having the same repetition rate. Combining may be performed using an Array Waveguide Grating (AWG). The signals may then be transmitted over a single medium and demultiplexed at the receiver side, to retrieve the clock, all the data signals, and the single photon sequence.

One technical effect of the disclosure relates to using a micro comb laser or a semiconductor mode lock laser (collectively referred to as micro comb lasers) for generating sequences of equidistant time domain pulses having different central frequencies, by using a single micro ring comb laser. The pulse trains are easy to generate and the time differences are highly accurate.

Another technical effect of the disclosure relates to using each pulse train for purposes such as carrying digital data, generating single photon sequence, or simply as an optical clock.

Yet another technical effect of the disclosure relates to combining the usage of two or more of the abovementioned pulse trains, thereby transmitting them over a single medium and utilizing their constant repetition rate.

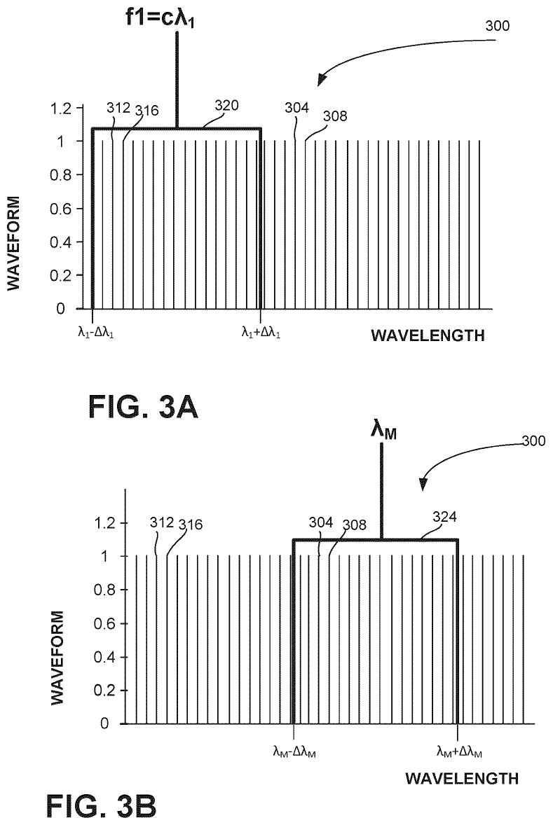

Referring now to FIG. 3A and FIG. 3B, showing selected groups of consecutive subcarriers, in accordance with some exemplary embodiments of the disclosure.

FIGS. 3A and 3B show a diagram 300 of the wavelengths emitted by a micro comb laser, such as wavelengths 304, 308 and 312. The frequencies corresponding to the wavelengths are equidistant, i.e., the difference between any two consecutive frequencies is constant. It is appreciated that although all amplitudes are shown to be identical this is not necessarily the case. By taking a consecutive group of the subcarriers shown for example in FIG. 1, the amplitudes are close, but not necessarily identical.

A first group of consecutive light waves, such as group 320 comprising 16 wavelengths may be selected. The wavelengths of the light waves in group 320 range between λ₁−Δλ₁ and λ₁+Δλ₁, and the average wavelength is λ₁.

A Fourier transform of the ensemble of the light waves provides a pulse train, as understood from the following formulation:

$$\begin{matrix}x ( t ) = T {\sum }_{n = - ∞}^{∞} δ ( t - nT ) & →︀ & x ( t ) = {\sum }_{n = - ∞}^{∞} {e}^{\frac{j 2 π n t}{T}} \\ ⇑ & & ⇓ \\ x ( f ) = T {\sum }_{n = - ∞}^{∞} {e}^{j 2 π nfT} & ←︀ & x ( f ) = T {\sum }_{n = - ∞}^{∞} δ ( f - n / T )\end{matrix}$$

Thus, a sum of equidistant frequencies in the frequency domain is translated to a pulse train in the time domain.

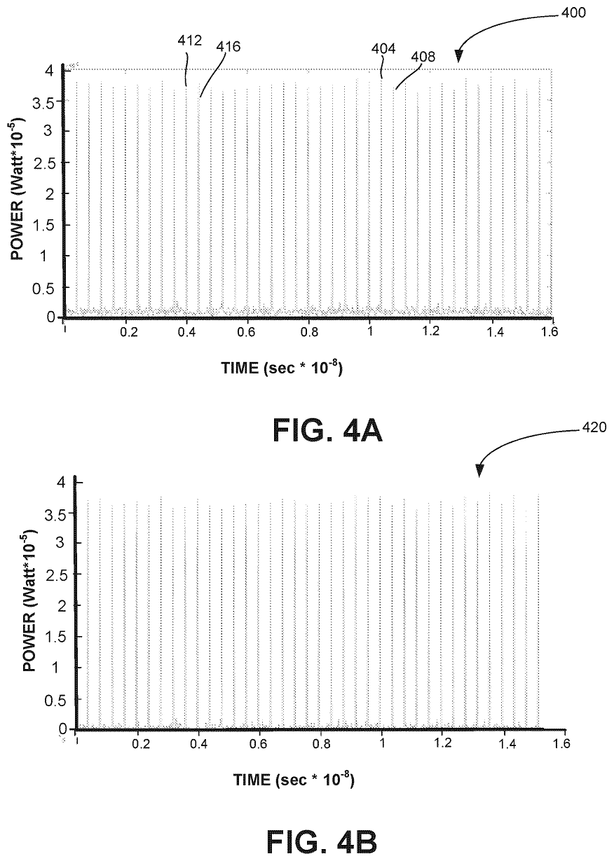

FIG. 4A shows a pulse train corresponding to the subcarriers as selected in FIG. 3A, including a typical pulse 404, wherein the time difference between any two consecutive pulses is constant. For example, the time difference between pulses 412 and 416 is equal to the time difference between pulses 404 and 408.

Similarly, a second group of consecutive light waves, such as group 324 of FIG. 3B comprising 16 wavelengths ranging between λ_{M}−Δλ_{M} and λ_{M}+Δλ_{M}, and a central wavelength of λ_{M}, may be selected, which also provides a pulse train 420 as shown in FIG. 4B. It is noted that the first group and the second group are different, i.e., do not contain the same collection of subcarriers.

Each pulse train has a unique wavelength, which is the same as the central frequency, e.g., the average frequency of the corresponding subcarrier group, such as λ₁ for the pulse train of FIG. 4A which is based on the subcarriers in group 320, and λ_{M} for the pulse train of FIG. 4B which is based on the subcarriers in group 324.

It is appreciated that the time differences between consecutive pulses in both pulse trains is equal, as this time difference is affected by the distance between the frequencies in the collection of subcarriers as output by the micro comb laser.

Although FIGS. 3A, 3B, 4A and 4B refer to two groups of subcarriers generating two pulse trains, the disclosure is not limited to two, and any number of groups may be generated, to form a corresponding number of pulse trains.

The width of the pulses in each pulse train depends on the number of subcarriers in the selected group, such that a group consisting of a larger number of wave lengths accounts for a narrower pulse and vice versa. In the extremal cases, taking one group consisting of all wavelengths provides for the narrowest pulse, but then only one pulse train is generated, and on the other extreme, generating a pulse train upon every single wavelength provides for overlapping wide pulses which are hardly distinguishable.

In some embodiments, the groups may be selected to be alien, i.e., not to have any common wavelength in common. This may be beneficial as it may provide for each pulse to have the maximal power, without splitting the power between pulses belonging to different pulse trains.

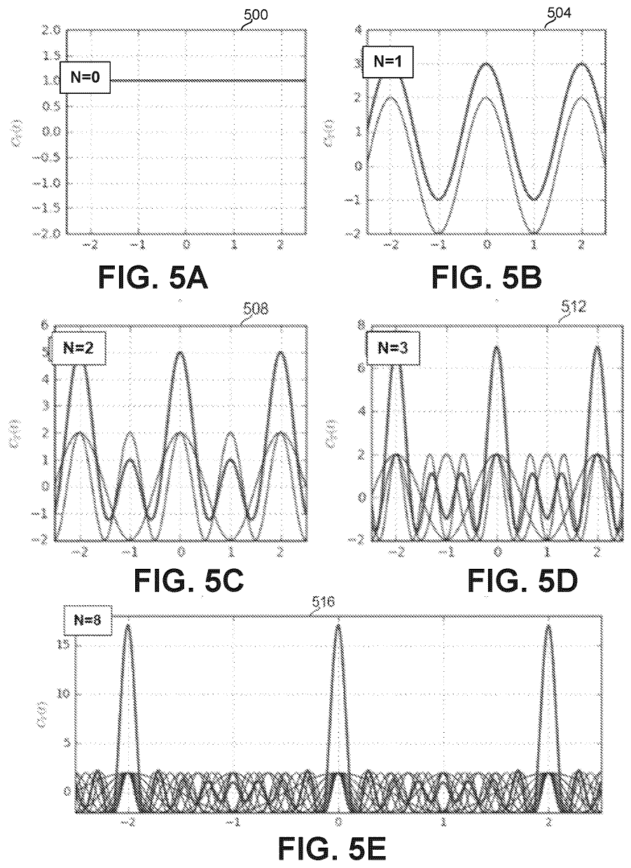

Referring now to FIGS. 5A-5E, showing obtained pulse trains when generating a pulse train by groups of subcarriers having a different number (N) of frequencies starting at zero frequency (DC) to the high harmonics. The example of FIG. 5A-5E relates to a baseband signal which is located at the zero frequency. However, the same effect is demonstrated for a bandpass signal located around the DFB laser frequency as shown in FIG. 1. Thus, in FIG. 5A graph 500 shows a null pulse train when no light waves are filtered, graph 504 in FIG. 5B shows the pulse train of a single wavelength, graph 508 in FIG. 5C shows the pulse train when two wavelengths are filtered, graph 512 in FIG. 5D shows the pulse train when three wavelengths are filtered, and graph 508 in FIG. 5E shows the pulse train when eight wavelengths are filtered.

It is seen that as the number of subcarriers increases the highest pulses become narrower and stronger relative to side lobes, while keeping the repetition rate.

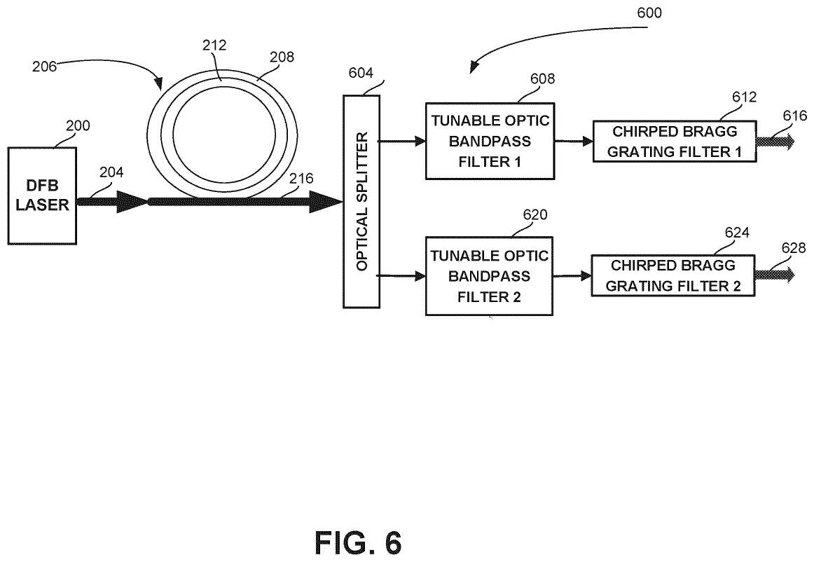

Referring now to FIG. 6, showing a schematic illustration of a sliced micro ring comb laser, in accordance with some exemplary embodiments of the disclosure.

DFB laser 200, light 204, MRM 206 comprising micro resonator ring 208 and thermal heater ring 212, and output light 216 are as described in association with FIG. 2 above.

Output light 216, comprising multiple frequencies complying with the diameter of micro resonator ring 208, may be provided to optical splitter 604, for splitting the power of the light beam into a plurality of light beams, such that each may be processed separately simultaneously.

Each split light beam goes through a filter, such as tunable optical bandpass filter 1 (608), or tunable optical bandpass filter 2 (620). The filter outputs certain frequencies, such as group 320 having a central frequency of λ₁, or group 324 having a central frequency of λ_{M}. Each of the selected groups of frequencies, which as described above form a pulse train in the time domain, the pulses of each pulse train having the central frequency of the corresponding group of frequencies.

Each of the bandpass filters can be a discrete element or implemented in integrated photonic platforms such as silicon, silicon nitride or other materials.

Each pulse train may be passed through a chirped Bragg grating filter, for example, chirped Bragg grating filter 1 (612) for the first pulse train and chirped Bragg grating filter 2 (624) for the second pulse train.

Chirped Bragg grating filter may reshape the pulses of the pulse train to the desired shape. Additionally or alternatively, the pulses may be shaped by high-dispersion fibers.

In some embodiments, Chirped Bragg grating filter may be implemented using optic fibers or integrated photonics such as but not limited to silicone photonics or silicone nitrite.

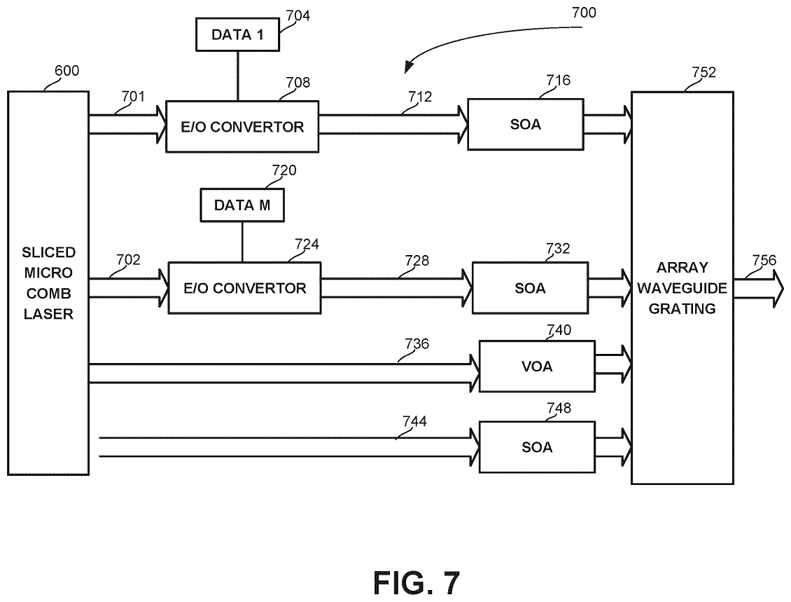

Referring now to FIG. 7, showing a schematic block diagram in a system for using a plurality of equidistant pulse trains, in accordance with some exemplary embodiments of the disclosure.

The system, generally referenced 700, receives a plurality of equidistant pulse trains from a micro comb laser, such as sliced micro ring comb laser 600 described in FIG. 6.

In some embodiments, one or more pulse trains, such as pulse train 701 or pulse train 702 may be encoded with digital or analog information. For example, in the digital case, digital data 1 (704) may be converted from digital data to optical data and used for modulating pulse train 701 by Electrical-to-Optical (E/O) converter 708. to obtain modulated pulse train 712. Similarly, digital data M (720) may be converted from digital data to optic data and used for modulating pulse train 702 by Electric-to-Optical (E/O) converter 724 to obtain modulated pulse train 728. E/O converter 708 or E/O converter 724 may be a Mach-Zenhder modulator, an ElectroAbsorber modulator, a micro ring modulator, a plasmonic modulator or any other type. E/O converter 708 or E/O converter 724 may be a discrete device or implemented on any integrated photonic platform to obtain modulated pulse trains 712 or 728.

Each of the modulated light beams, such as modulated pulse train 712 or modulated pulse train 728 may be input into a semiconductor optical amplifier (SOA), such as SOA 716 for modulated pulse train 712 or SOA 732 for modulated pulse train 728.

SOA 716 or SOA 732 may amplify the pulses to the required level.

Another pulse train, such as pulse train 736 may be provided to a variable optical attenuator (VOA), such as VOA 740, for attenuating the pulses into single photons, thereby generating a single photon sequence. The sequence may be of high rate, equal to the repetition rate of the pulse train, such as 50 GHz, 100 GHz, 200 GHz, or the like. The required repetition rate may be achieved by the proper dimensions of the micro ring. The single photon sequence may be used as a quantum bit source.

Yet Another pulse train, such as pulse train 744 may or may not be provided to a SOA 748 without being modulated, SOA 748 may amplify the pulses, which may then be used as an optical clock, due to the accuracy of the pulse train.

It is appreciated that although only two pulse trains are shown to be modulated with electric data, the system is not limited to two such pulse trains, and any number of pulse trains may be used, as determined according to the desired pulse width. It is also appreciated that multiple single photon sequences may be generated, each with a different wavelength and that multiple electric clocks may also be implemented, but that may cause useless redundancy.

Some or all of the abovementioned outputs may be fed into array waveguide grating (AWG) 752, where they may be multiplexed into output unified light beam 756.

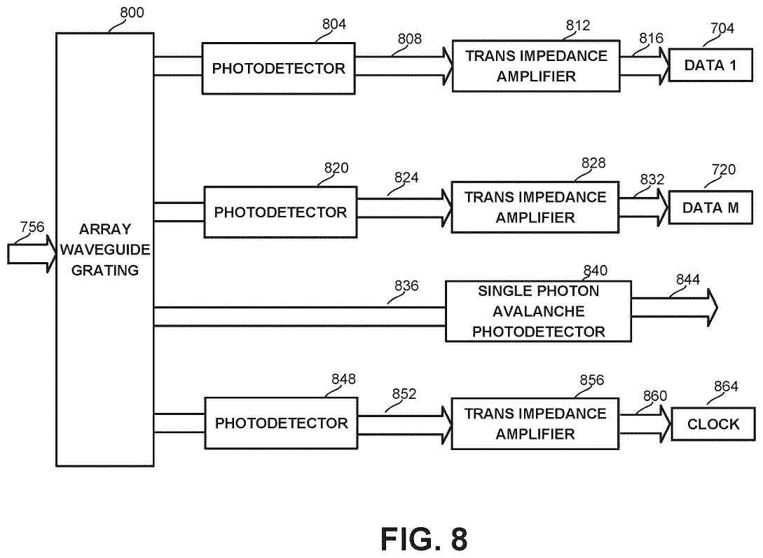

Referring now to FIG. 8, showing a schematic block diagram of a receiver system for separating and using the various components of output light 756, in accordance with some exemplary embodiments of the disclosure.

Unified light beam 756 output from AWG 756 of the transmitter side, comprising one or more streams of data, an optical clock, and/or one or more single photon sequences which may be used as quantum data and quantum key, may be received by an AWG 800 on the receiver side, which may demultiplex it into the various components.

Thus, AWG 800 may output a plurality of pulse trains, such as pulse train 808 and pulse train 824. Each pulse train may be provided to a corresponding photodetector, such as photodetector 804 for pulse train 808, or photodetector 820 for pulse train 824.

The photodetectors may output electrical signals in accordance with the input optical signal, such as electrical signal 808 output by photodetector 804 or electrical signal 824 output by photodetector 820.

In some embodiments, each electrical signal may be provided to a corresponding trans-impedance amplifier, such as trans-impedance amplifier 812 for electrical signal 808 or trans impedance amplifier 828 for electrical signal 824, and may output an amplified electrical signal, such as electrical signal 816 or electrical signal 832. The electrical signals as well as the amplified electrical signals may carry the data with which the light waves output by the laser source and sliced micro comb laser such as sliced micro ring comb laser 600, such as data 1 (704), data M (720) or additional data. Thus, electrical signal 816 may carry data 1 (704) and electrical signal 832 may carry data M (720).

In some embodiments, AWG 800 may also output a single photon sequence 836, which may be provided to a single photon avalanche photodetector (SPAD) 840 which may detect the single photons and output a corresponding electrical signal 844.

In some embodiments, AWG 800 may also output yet another one or more pulse trains which have not been encoded with data, such as pulse train 836. The pulse train(s) such as pulse train 836 may also be fed into a photodetector, such as photodetector 848 to output an electrical signal 852, which may be amplified by trans impedance amplifier 856 and output a signal 860 which may be used as a clock signal 864.

Thus, the same micro ring comb laser may be used for the generation of the various signals: one or more pulse trains for data transmission, a pulse train for the clocking for various purposes, and one or more the single-photon sources, thereby generating a multi functional light source from a single micro comb laser.

It is appreciated that since all the outputs of AWG 800 are of the same repetition rate, clock 864 may be used for synchronizing all other outputs of the system including data 1 (704), data M (720) and electrical signal 844.

It is appreciated that the disclosure is not limited to two data streams, one photon sequence and one clock signal, rather any combination of any number of the above may be provided.

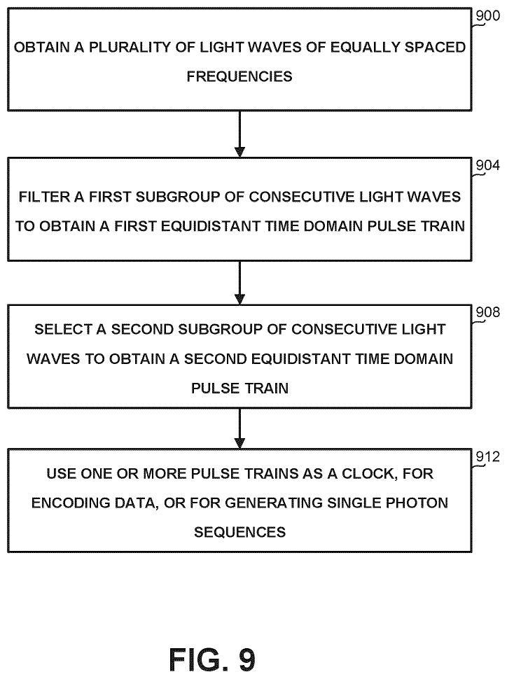

Referring now to FIG. 9, showing a flowchart of a method for generating and using pulse trains from a micro comb laser, in accordance with some exemplary embodiments of the disclosure.

On step 900, a plurality of light waves of equally spaced frequencies may be received from a source, such as a micro comb laser.

On step 904, a first consecutive group of the consecutive light waves may be filtered, which when examined in the time domain provides a first accurate equidistant (in time) pulse train.

On step 908, a second consecutive group of the consecutive light waves may be filtered, which when examined in the time domain provides a second accurate equidistant (in time) pulse train.

On step 912, any one or more of the pulse trains may be used as a clock, for encoding data, generating a single photon sequence, or other usages.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, such as “C”, C#, C++, Java, Phyton, Smalltalk, or others. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method comprising:
obtaining a plurality of coherent subcarriers, each of the plurality of coherent subcarriers having a subcarrier frequency out of a collection of subcarrier frequencies, wherein the collection of subcarrier frequencies are equally spaced;
filtering a first group of subcarriers having consecutive frequencies of the collection of subcarrier frequencies, thereby obtaining a first sequence of equidistant pulses in time domain; and
filtering a second group of subcarriers having consecutive frequencies of the collection of carrier frequencies, thereby obtaining a second sequence of equidistant pulses in the time domain, wherein the second group is different from the first group,
thereby obtaining at least two sequences of equidistant time domain pulses, the at least two sequences of equidistant time domain pulses having different wavelengths.

2. The method of claim 1, wherein a first wavelength of the first sequence of equidistant pulses in the time domain depends on a central frequency of the first group of subcarriers, and a second wavelength of the second sequence of equidistant time domain pulses depends on a central frequency of the second group of subcarriers.

3. The method of claim 1, wherein the first group of subcarriers and the second group of subcarriers do not have any common subcarrier.

4. The method of claim 1, wherein
a smaller number of subcarriers in the first group of subcarriers provides for wider pulses in the first sequence of equidistant time domain pulses,
a larger number of subcarriers in the first group of consecutive light waves provides narrower pulses in the first sequence of equidistant time domain pulses,
a smaller number of subcarriers in the second group of consecutive light waves provides wider pulses in the second sequence of equidistant time domain pulses, and
a larger number of subcarriers in the second group of consecutive light waves provides narrower pulses in the second sequence of equidistant time domain pulses.

5. The method of claim 1, further comprising providing the first sequence of equidistant time domain pulses to a first Chirped Bragg Grating filter to obtain a first sequence of reshaped equidistant time domain pulses, or providing the second sequence of equidistant time domain pulses to a second Chirped Bragg Grating filter to obtain a second sequence of reshaped equidistant time domain pulses.

6. The method of claim 5, further comprising transmitting the first sequence of reshaped equidistant time domain pulses or the second sequence of reshaped equidistant time domain pulses as modulated to a semiconductor optical amplifier (SOA) for amplification.

7. The method of claim 5, further comprising modulating the first sequence of reshaped equidistant time domain pulses or the second sequence of reshaped equidistant time domain pulses.

8. The method of claim 7, further comprising transmitting the first sequence of equidistant time domain pulses or the second sequence of equidistant time domain pulses as modulated to a SOA for amplification.

9. The method of claim 1, further comprising using the first sequence of equidistant time domain pulses or the second sequence of equidistant time domain pulses as an optical clock.

10. The method of claim 1, further comprising providing the first sequence of equidistant time domain pulses to a first Variable Optical Attenuator (VOA) to obtain a first high rate sequence of single photons at a wavelength of the first sequence of equidistant time domain pulses, or providing the second sequence of equidistant time domain pulses to a second VOA to obtain a second high rate sequence of single photons at a wavelength of the second sequence of equidistant time domain pulses.

11. The method of claim 10, further comprising using the first high rate sequence of single photons or the second high rate sequence of single photons as quantum bits source.

12. The method of claim 1, wherein each of the first group of consecutive light waves and the second group of consecutive light waves, comprises at least 8 light waves.

13. A system comprising:
a laser source for emitting a light wave;
a mechanism for generating a plurality of coherent subcarriers from the light wave, each of the plurality of coherent subcarriers having a subcarrier frequency out of a collection of carrier frequencies, wherein the collection of subcarrier frequencies are equally spaced;
at least a first filter for filtering a first group of subcarriers having consecutive frequencies of the collection of subcarrier frequencies, thereby obtaining a first sequence of equidistant pulses in time domain;
at least a second filter for filtering a second group of subcarriers having consecutive frequencies of the collection of subcarrier frequencies, thereby obtaining a second sequence of equidistant pulses in time domain;
at least one item selected from the group consisting of:
an electrical to optical convertor for converting electrical data into optical data and modulating the first sequence of equidistant pulses or the second sequence of equidistant pulses and a semiconductor optic amplifier for amplifying the light wave to obtain at least one optical data signal;
a variable optical attenuator for transforming the first sequence of equidistant pulses or the second sequence of equidistant pulses into a single photon sequence; and
a semiconductor optical amplifier for amplifying the light wave, thereby creating an optical clock signal, and
an array waveguide grating for multiplexing the at least one optical data signal, the single photon sequence or the optical clock signal into a unified light beam.

14. The system of claim 13, further comprising a receiver system comprising:
an array waveguide grating for demultiplexing the unified light beam; and
at least one item selected from the group consisting of:
a photodetector for receiving a pulse train demultiplexed from the unified light beam, and a trans impedance amplifier for obtaining electronic data or a clock pulse; and
a single photon avalanche photodetector for obtaining a single photon sequence.
